(19) United States
(12) Patent Application Publication
(10) Pub. No.: US 2005/0045373 A1
(43) Pub. Date: Mar. 3, 2005

(54) Portable media device with audio prompt menu

(76) Inventor: Joseph Born, Lincolnwood, IL (US)

Correspondence Address: MORGAN, LEWIS & BOCKIUS, LLP., 2 PALO ALTO SQUARE, 3000 EL CAMINO REAL, PALO ALTO, CA, 94306, US

(21) Appl. No.: 10/446,908

(22) Filed: May 27, 2003

(51) Int. Cl. H05K 1/03; H05K 1/09

(52) U.S. Cl. 174/254; 174/255; 174/256; 257/700

(57) ABSTRACT

Once an audio prompt has been stored on the portable media device, the audio prompt menu is played. Subsequently, an input from a user of the portable media device is then received in response to the audio prompt menu. A command is subsequently transmitted to a remote computer. The command requests the remote computer to perform an action based on the user's input. The portable media device includes a portable media device housing containing a processor, a power source, a user interface device, communications circuitry, at least one input/output (i/o) port, and a memory. The memory includes an operating system, a media database, communication procedures for communicating with a remote computer, and instructions for performing the above described method.

### BACKGROUND OF THE INVENTION

1. Field of the Invention

The invention relates generally to portable audio players, such as MP3 players. More particularly, the invention is directed to a portable audio device with an audio prompt navigation menu.

2. Description of Related Art

Since the advent of the audio cassette, portable audio players have enjoyed widespread popularity. Portable audio players allow a user to listen to audio in virtually any setting by freeing the user from the mobility constraints imposed by bulky home-based audio systems.

The introduction of the portable CD player in the early 1980's brought digital audio fidelity to the portable audio player. Digital audio compression technologies later allowed digital audio to be stored in a significantly smaller file with little degradation of audio quality. However, it was not until the ease of data distribution provided by the Internet that compressed digital audio found widespread use.

Now, for the first time in history, the Internet allows digital audio to be downloaded (transferred and stored for later playback) and/or streamed (played as it is being sent but not permanently stored) directly to a user's computer. The most common digital audio compression algorithms in use today are MPEG-1 Audio Layer 3 (better known as MP3) and Windows Media Audio (WMA), with Ogg-Vorbis becoming increasingly popular. The popularity of compressed digital audio, in particular MP3 files, and ever cheaper and smaller memory devices, led to the introduction of the portable MP3 player in 1998.

Because portable audio players are often physically carried by the user, it is desirable to make these players as small and lightweight as possible. Therefore, to compete in a crowded and competitive portable audio player market, successful manufacturers must continually seek ways to reduce the size and/or cost of their portable audio player(s).

Generally, there are a number of ways to reduce the size and/or cost of a portable audio player. For example, a manufacturer may eliminate or reduce the size and/or cost of the circuitry, battery, memory, and/or other components. However, while advances in circuitry, chip size, and battery technology are continually taking place, such advances are evolutionary rather than revolutionary. Similarly, while memory capacity in the same package size has increased significantly, the package size has typically remained the same.

An overlooked way of reducing the size of portable audio players is by eliminating or reducing the size of the portable device's input/output (i/o) devices. Designers of portable audio devices cannot completely eliminate the i/o devices, as there will always be a need for users to interact with the portable audio devices to control settings such as selecting the media to play, the track order (sequential or random), repeating tracks, deleting tracks, etc. As such, it is desirable to reduce the overall device size by reducing the device's i/o devices. Such a reduction is size should also preferably reduce the cost of the device.

In addition, most portable media players require a user to control the device through a screen driven user interface and keypad, such as is commonly used in cellular phones. In many situations, however, navigating through a screen driven user interface is impractical and dangerous, such as while exercising or driving. Indeed, the Harvard Center for Risk Analysis recently reported that cellular telephone use by drivers may result in some 2,600 deaths, 330,000 moderate to critical injuries, 240,000 minor injuries and 1.5 million instances of property damage per year in the United States alone. Accordingly, a user interface that reduces the need to view the portable audio player while navigating through the device is highly desirable.

Finally, it is desirable that users of digital audio on a portable audio device can provide feedback that can be used to provide additional interactivity functionality when the device is connected with other computers or computer type devices. This type of feedback could be used in conjunction with applications and services such as recommendation engines or the like.

In light of the above, there is a need for a portable audio device and method that addresses the abovementioned drawbacks, while being convenient and easy to use.

### BRIEF SUMMARY OF THE INVENTION

The invention provides a digital audio device that uses an audio prompt menu structure either as a substitute or to, or to augment a visual display of a portable media device. Accordingly, the relative size and cost of the portable media device is substantially reduced.

According to the invention there is provided a method for using an audio prompt menu on a portable media device, such as an MP3 player. Once an audio prompt has been stored on the portable media device, the audio prompt menu is played. An input from a user of the portable media device is then received in response to the audio prompt menu. A command is subsequently transmitted to a remote computer. The command requests the remote computer to perform an action based on the user's input.

In a preferred embodiment, before the audio prompt is stored, it is synthesized from a textual description of a menu. This synthesis either occurs on the portable media device itself or at a remote computer, such as a client computer or server. In addition, the portable media device may initially request an additional menu before the synthesis occurs.

The audio prompt is preferably stored together with other media played on the portable media device, as a compressed audio file, such as an MP3 file. The audio prompts preferably form part of a menu structure containing instructions for deleting a media file, instructing another remote computer to purchase a media file, instructing another remote computer to recommend media, instructing the remote computer to delete a media file, instructing the remote computer to add a media file, instructing the remote computer to modify a media file, instructing the remote computer to email a media file, instructing the remote computer to delete an index of a media file from a playlist, or instructing the remote computer to take some other action with respect to a media file or a menu item.

According to the invention, there is also provided a method for updating an audio prompt menu structure on a portable media device. A command for adding an additional menu to or deleting an existing menu from a navigation database on the portable audio device is received at a portable media device. Thereafter, the command to update the navigation database is invoked, and either an audio description of the additional menu is stored on the portable media device for later use in an audio prompt menu structure or the audio description of the existing menu is deleted from the portable media device.

Still further, according to the invention there is provided a method for dynamically generating an audio prompt menu on a portable media device. Once it is determined that a menu structure on a portable device requires presenting a description of a media file, a textual description of the media file on the portable media device is located. The textual description is then synthesized into an audio description on the portable media device. An audio prompt menu is generated that at least partially incorporates the audio description, and that audio prompt menu is played on the portable media device.

According to yet another embodiment of the invention there is provided a portable media device. The portable media device includes a portable media device housing containing a processor, a power source, a user interface device, communications circuitry, at least one input/output (i/o) port, and a memory. The memory preferably includes an operating system, a media database, communication procedures for communicating with a remote computer, and other instructions. These other instructions include instructions for storing an audio prompt in the media database, instructions for playing the audio prompt menu, instructions for receiving in response to the audio prompt menu an input from a user of the portable media device via the user input interface, and instructions for transmitting a command to a remote computer via the communications circuitry, where the command requests the remote computer to perform an action based on the input. The memory also preferably included a text to audio synthesizer and media stored in the media database.

Accordingly, the above described invention eliminates the need for a visual display, thereby reducing the size and cost of portable media devices. As the user does not have to look as a display or screen, this portable media device is particularly well suited to situations where viewing a screen is dangerous, such as while driving or participating in sport. An audio prompt menu structure is also advantageous to the visually impaired. Finally, the portable media device provides is easily upgradeable and customizable.

### BRIEF DESCRIPTION OF THE DRAWINGS

For a better understanding of the nature and objects of the invention, reference should be made to the following detailed description, taken in conjunction with the accompanying drawings, in which:

FIG. 1 is a diagrammatic view of a system for updating an audio prompt menu structure on a portable media device, according to an embodiment of the invention;

FIG. 2 is a block diagram of the portable media device shown in FIG. 1;

FIG. 3 is a block diagram of the server 106 and/or the client computer 102 shown in FIG. 1;

FIG. 4A is a three-dimensional view of a portable media device, according to an embodiment of the invention;

FIG. 4B is a three-dimensional view of another portable media device, according to another embodiment of the invention;

FIG. 5 is a flow chart of three methods for utilizing an audio prompt menu on a portable media device, according to three different embodiments of the invention;

FIG. 6 is a flow chart of a method for navigating through an audio prompt menu structure on a portable device, according to an embodiment of the invention; and

FIG. 7 is a flow chart of a method for generating a menu described in FIG. 6.

Like reference numerals refer to corresponding parts throughout the several views of the drawings.

### DETAILED DESCRIPTION OF THE INVENTION

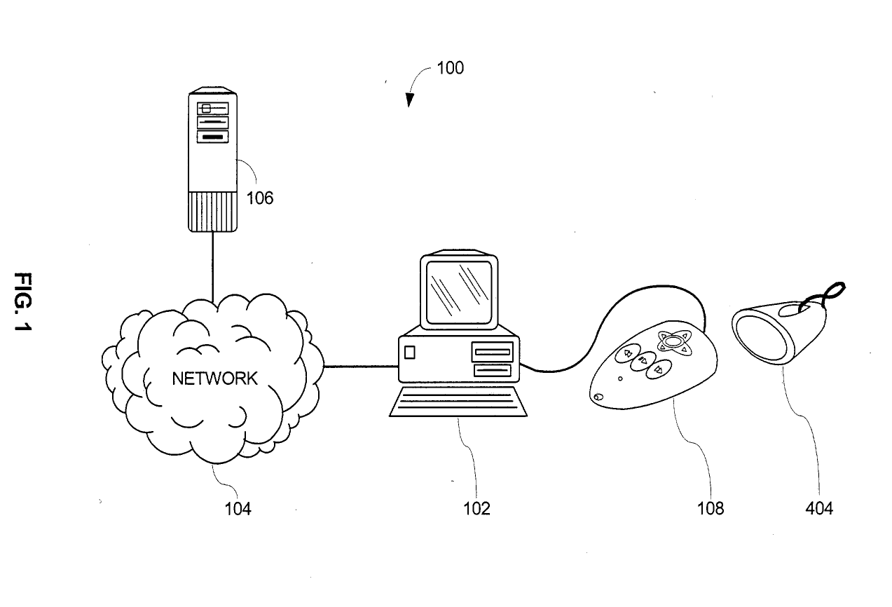

FIG. 1 is a diagrammatic view of a system 100 for updating an audio prompt menu structure on a portable media device 108. The system 100 preferably includes a portable media device 108, at least one server 106, and at least one client computer 102. The system 100 also preferably includes a network 104. In a preferred embodiment, the server 106 and client computer 102 are any type of computing devices, such as desktop, laptop, or tablet computer, while the network 104 is a WAN or a LAN, but preferable the Internet.

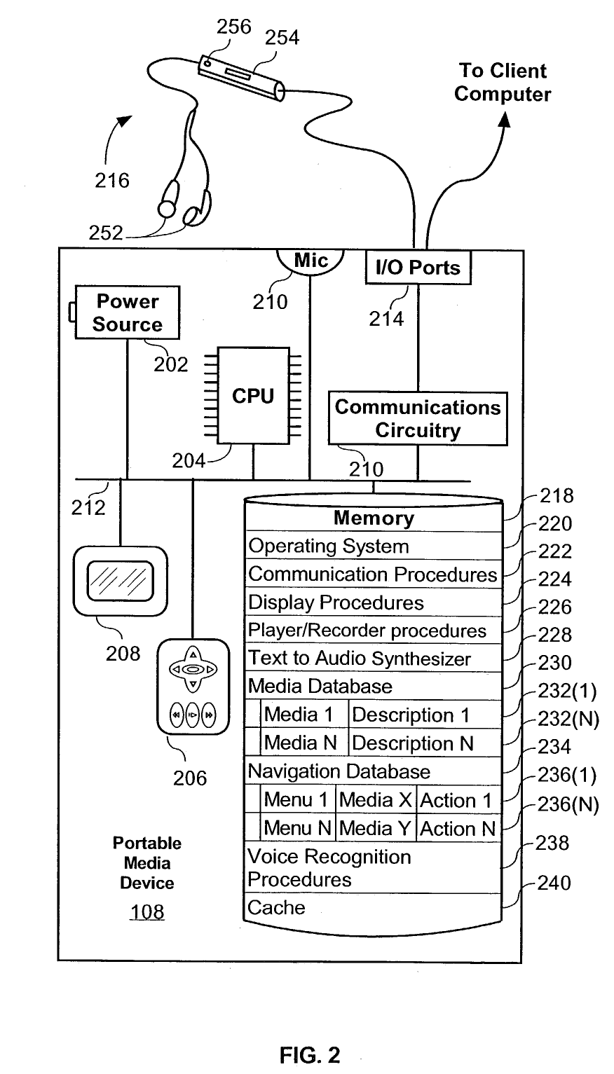

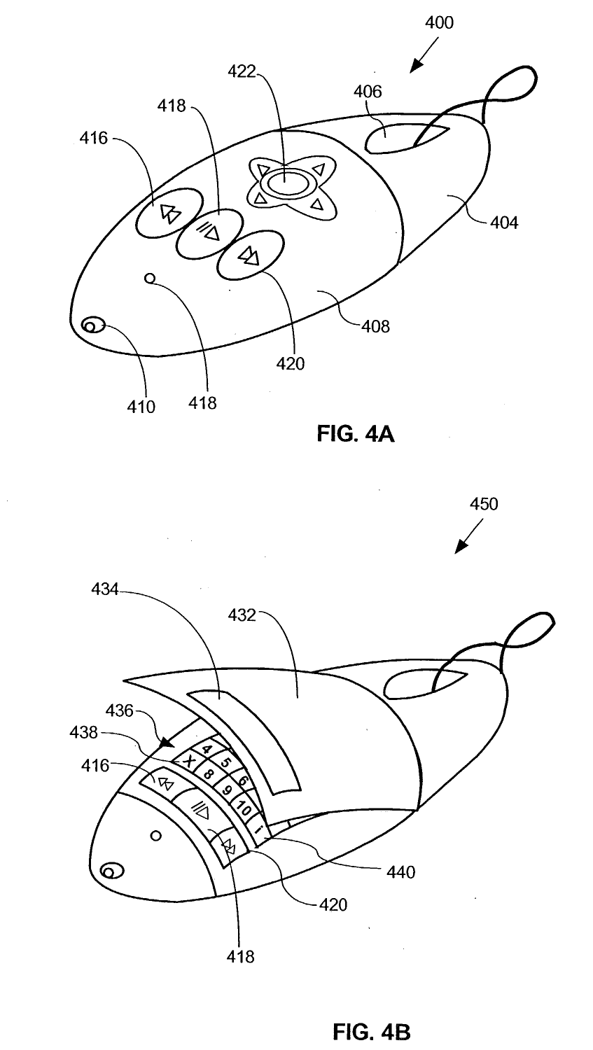

The portable media device 108 is any self controlled media storage and playback device that is small enough to be easily carried by a person, preferably in the palm of one hand. Furthermore, the portable media device 108 is preferably configured to store media files including: video files, audio files, data files, or the like. An example of an audio file is an MP3 file, an example of a video file is an MPEG-4 (Motion Picture Experts Group Layer-4 Video) file, and an example of a data file is a word document. Further details of the portable media device are described below in relation to FIGS. 2, 4A, and 4B. In a preferred embodiment, the portable media device is configured to play the media file.

The portable media device 108 is preferably coupled to the client computer 102 via any suitable connection, such as via a Universal Serial Bus (USB) connection, IEEE 1394 Firewire™ connection, Ethernet connection, wireless connection, infra-red connection, or the like. In the embodiment shown in FIG. 1, the portable media device 108 includes a male USB plug under a removable cap 404. The male USB plug, plugs directly into an open USB port on the client computer 102. Also in a preferred embodiment, the client computer 102 and the server 106 are coupled to the network 104 via any suitable connection, such as a modem connection, Ethernet connection, broadband connection, wireless connection, infra-red connection, or the like. These connections may be established over coaxial cable, multi-strand copper wire, optical fiber, or the like.

In an alternative embodiment, no client computer 102 is present and the portable media device 108 communicates directly with the server 106. For example, the portable device 108 may include cellular telephone communication circuitry which communicates with the server 106 via a cellular telephone network (network 104).

FIG. 2 is a block diagram of the portable media device 108 shown in FIG. 1. The portable device 108 preferably includes: at least one data processor or central processing unit (CPU) 204; a memory 218; user interface devices, such as a display 208 and a keypad 206; communications circuitry 210 for communicating with the network 104 (FIG. 1), server 106 (FIG. 1), and/or client computer 102 (FIG. 1); input and output (I/O) ports 214 coupled to the communication circuitry 210; a microphone 210; a power source 202, such as a battery; and at least one bus 212 that interconnects these components. It should be noted, however, that the preferred embodiment of the instruction does not include a display 208.

The portable media device 108 is preferably configured to couple to a headset or speakers 216 via any suitable means, such as a wired or wireless connection. The headset has speakers 252, and an optional microphone 256 and/or optional audio controls 254.

Memory 218 preferably includes an operating system (OS) 220, such as a proprietary OS, LINUX, or WINDOWS CE having instructions for processing, accessing, storing, or searching data, etc. A suitable OS is disclosed in Applicant's co-pending U.S. patent application Ser. No. 10/273,565, which is hereby incorporated by reference herein. Memory 218 also preferably includes communications procedures 222 for communicating with the network 104 (FIG. 1), the server 106 (FIG. 1), and/or the client computer 126 (FIG. 1). The communication procedures 222 are also preferably used to communicate between the portable media device 108 and the user using the headset or speaker 216. Still further, the communication procedures are also preferably used to download media onto the portable media device 108.

The memory 218 also preferably includes: player and/or recorder procedures 226 for playing and/or recording media to media files, such as playing audio through the headset speakers 252 and/or recording audio through the microphone(s) 210 or 256; a text to audio synthesizer 228 for converting text into speech that is preferably saved as a media (audio) file; a media database 230 including media, where each media file includes a textual description (meta data) (such as an ID3 tag) and/or audio description and associated media 232(1)-(N); a navigation database 234 containing multiple menus, where each menu includes an index to an associated media file in the media database and an associated action 236(1)-(N); voice recognition procedures for recognizing recorded speech as navigation instructions 238; and a cache 240 for temporarily storing data. In an alternative embodiment, the memory 218 also includes display procedures 224 for displaying information on the display 208.

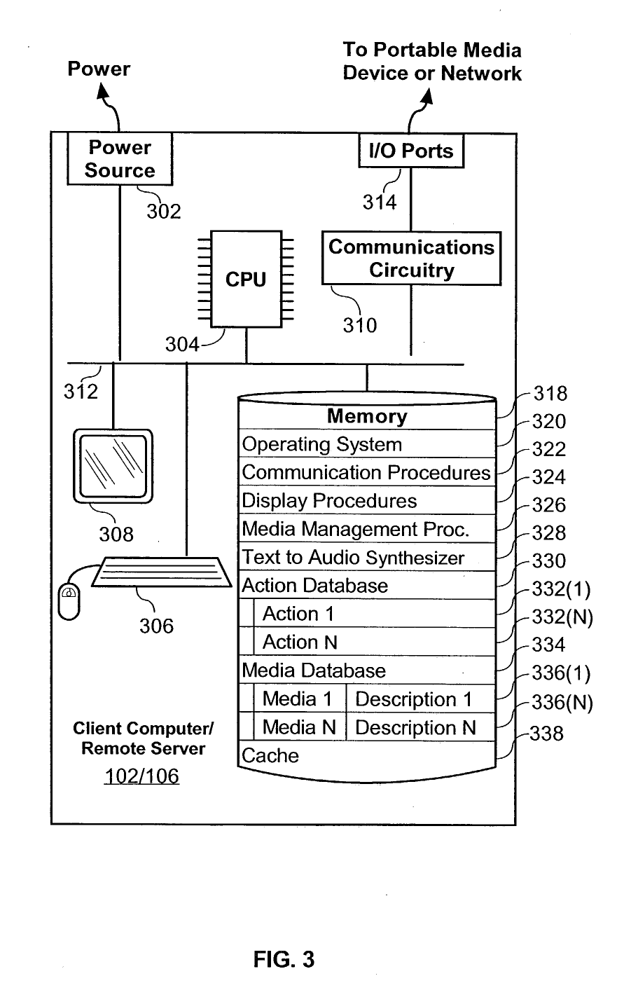

FIG. 3 is a block diagram of the server 106 and/or the client computer 102 shown in FIG. 1. The server 106 and/or the client computer 102 preferably include: at least one data processor or central processing unit (CPU) 304; a memory 318; user interface devices, such as a monitor 308, keyboard, and mouse 306; communications circuitry 310 for communicating with the network 104 (FIG. 1), server 106 (FIG. 1), client computer 102 (FIG. 1), and/or portable media device 108 (FIG. 1); input and output (I/O) ports 314 coupled to the communication circuitry 310; a power source 302 configured to be coupled to a source of power; and at least one bus 312 that interconnects these components.

Memory 318 preferably includes an operating system (OS) 320, such as a LINUX, or WINDOWS having instructions for processing, accessing, storing, or searching data, etc. Memory 318 also preferably includes communications procedures 322. Where the device depicted in FIG. 3 is the client computer 102, the communication procedures are used for communicating with the network 104 (FIG. 1), server 106 (FIG. 1), and/or portable media device 108 (FIG. 1). In particular, the communication procedures 322 are used for synchronizing media files between the client computer and the portable media device. Where the device depicted in FIG. 3 is the server 106, the communication procedures are used for communicating with the network 104 (FIG. 1), client computer 102 (FIG. 1), and/or portable media device 108 (FIG. 1).

The memory 318 also preferably includes: display procedures 324 for displaying information on the monitor 308; media management procedures 326 for synchronizing and managing the media on the portable media device; a text to audio synthesizer 328 for converting a text into speech, which is saved as a media (audio) file; a action database 330 including multiple actions 332(1)-(N) therein; a media database 334 storing media, where each media file preferably includes a textual description (such as an ID3 tag) and/or an audio description associated with the media 336(1)-(N); and a cache 338 for temporarily storing data.

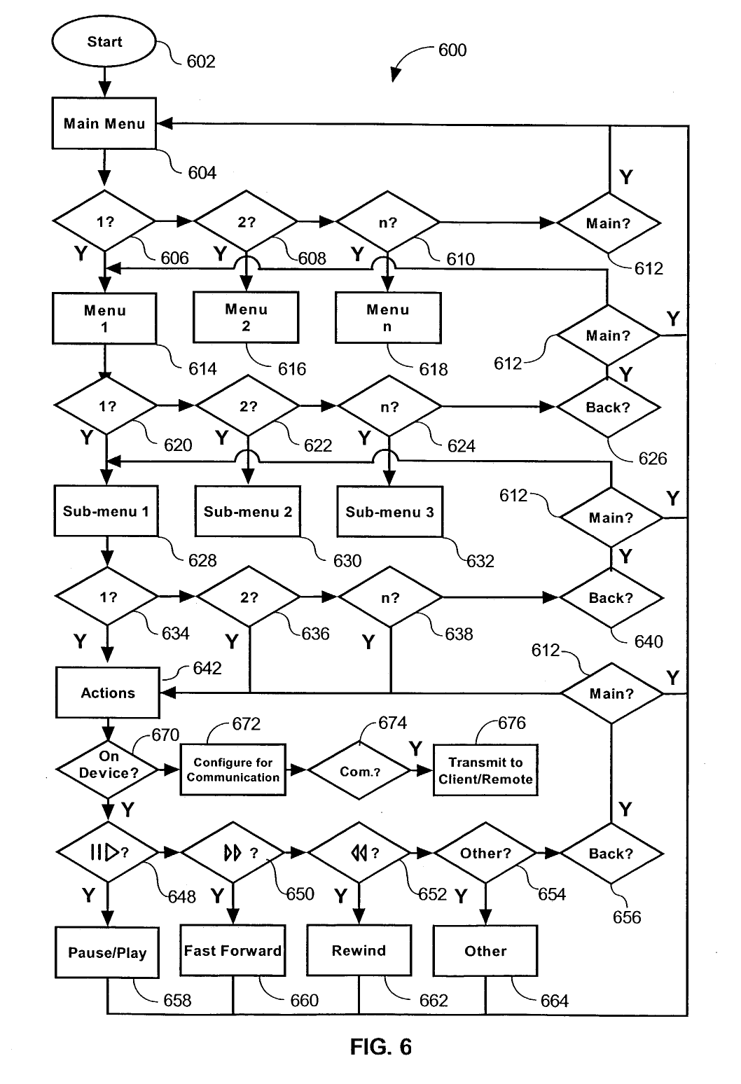

FIG. 4A is a three-dimensional view of a preferred portable media device 400. This preferred portable media device 400 does not include a display 208 (FIG. 2), thereby reducing the size and cost of the device. Instead, a user navigates through the media on the portable media device 400 using an audio prompt menu made up of audio files describing each command or media file, as described below in relation to FIG. 6. The portable media device 400 preferably includes a removable cap 404 that covers a communication outlet or jack, such as a male USB plug. The space under the cap can also be used to store the device's headset when not in use. A hole 406 in the cap 404 is preferably provided for a user to couple the portable media device to a key ring or to wear the device around the user's neck on a necklace.

The portable media device 400 also includes a body 408 housing the portable media device's electronics. The keypad 206 described in (FIG. 2) preferably includes a navigation joystick 422 that is used to navigate up, down, forward, or backward. The keypad 206 (FIG. 2) also preferably includes basic media player controls, such as a play/pause button 418, a rewind button 416, and a fast-forward button 420. Also preferably provided are a microphone 210 (FIG. 2), shown as reference numeral 418, and a headphone jack 410, shown as reference numeral 410. It should be appreciated that the joystick 422 and keypad 206 can be combined into a single component.

FIG. 4B is a three-dimensional view of another preferred portable media device 450. Unlike the device 400 shown in FIG. 4A, this portable media device 450 houses a keypad 436 under a hinged cover 432. A hole 434 in the cover 432 allows access to the basic player controls 416, 418, and 420, even when the cover 432 is closed. The keypad 436 preferably includes a numeric keypad with a few buttons reserved for dedicated functions, such as delete 438 or information 440 buttons.

The keypad 436 is preferably concealed under the cover 432 during typical use so as not to interfere with the primary operation of the device, namely using the basic player controls. In use, when a user wishes to modify the configuration settings or to input additional information to the device, the user can open the cover 432 to reveal the keypad 436. During such configuration, the user is guided through a series of audio prompts, as described below in relation to FIG. 6. In a preferred embodiment, the action of opening the cover 432 causes the device to perform a dedicated action, such as muting audio playback and playing a main audio menu in anticipation of user input.

In one embodiment, the keypad 436 is used to initiate a keyword search by typing an alphanumeric string into the keypad with an audio confirmation of each letter being played back to the user or displayed on a display if provided. In addition, where a display is provided, the display could be used to provide visual feedback in those cases where audible feedback is not appropriate or possible, such as while making a recording or where a headset is not available. In such a case, the display could indicate that a recording is underway, or has completed, as appropriate.

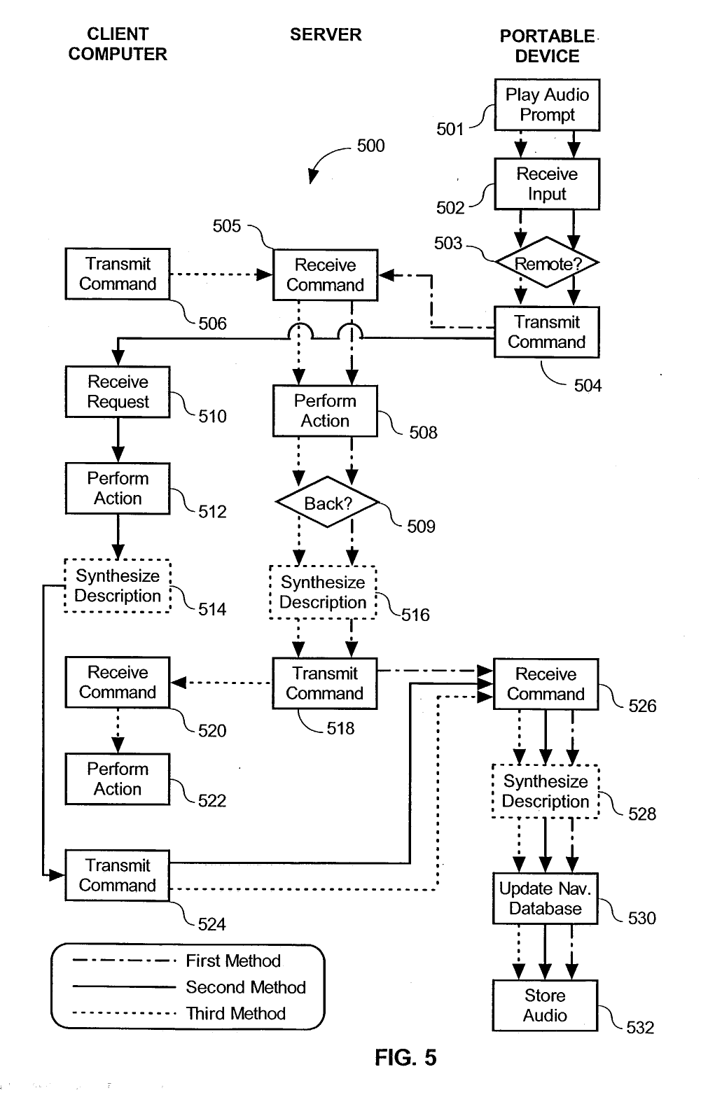

FIG. 5 is a flow chart of three methods 500 for using an audio prompt menu on a portable media device 108 (FIGS. 1 and 2). These three methods are: (1) when the portable media device requests the server to perform an action, as indicated by the chain line; (2) when the portable media device requests the client computer to perform an action, as indicated by the solid line; or (3) when the client computer requests the server to perform an action, as indicated by the dashed line. An action is any procedure performed on the portable media device, client computer, or server. For example, an action may add an additional menu to the portable device's menu structure; request the download of new media; request media from similar artists; add commands to the portable media device, such as speed-up or slow-down; or the like. Requests to perform an action are preferably sent between devices in a datagram or packet. These three methods will now be separately described.

The first method is initiated when a user of the portable media device would like the server to perform an action. For example, a user of the portable media device would like to add an additional menu to the portable media device, such as a menu through which the user can request music from similar artists to the artist who's media is currently being played on the portable media device.

The first method starts by the player procedures 226 (FIG. 2) playing an audio prompt menu at step 501. This may be initiated by the user pressing a power button or opening the cover 432 (FIG. 4B) of the portable media device. Each audio prompt menu 1-N 236(1)-(N) (FIG. 2) is associated with a particular media file stored in the media database 230. For instance, a main menu is associated with an MP3 file containing a main menu audio prompt. For example, the portable media device plays a main audio menu through the headset 216 (FIG. 2), such as “Welcome to NEUROS, press or say “1” for genres, press or say “2” for artists, press or say “3” for titles, please press or say “4” for updating the library on the attached client computer, press or say “5” for downloading additional menus, . . . , press or say “main” to repeat.”

The operating system 220 (FIG. 2) then waits for user input. Once the user has selected one of the choices presented in the audio prompt menu, the user selection or input is received by the portable media device at step 502. For example, the user can press or say “4.” If the user says “4,” the user's response is recorded through the microphone 210 (FIG. 2) as a media file 236(1) (FIG. 2) by the recorder procedures 226 (FIG. 2). The voice recognition procedures 238 then determine the user's precise input. Accordingly, the audio prompts allow a user to use the keypad or voice commands to navigate through the audio prompt menu. In a preferred embodiment, the forward position of the joystick selects an item, the back position replays the prior menu, and the up and down positions play sequential items in a menu. In other words, the audio prompts play a list of items in a particular menu. Upon hearing one of these audio prompts, the user may select that prompt by using the right joystick position to navigate forward through menu levels. Conversely, the user could use the left joystick position to back out of a particular menu level in which case the user would be presented with the prior menu. In this way, experienced users would learn to visualize the menu structure and would be able to interrupt the audio prompts to expedite their required actions.

If the input is a request for a remote computer, such as the server, to perform an action at step 503, then a command to perform the action is transmitted by the communication procedures 222 (FIG. 2) to the server to perform the action at step 504. This command preferably contains the name of the particular action to be performed. In a preferred embodiment, the command is first sent to the client computer 102 (FIG. 1), which then sends the command to the server 106 (FIG. 1) via the network 104 (FIG. 2). Alternatively, the portable media device may send the command directly to the server, such as via a cellular telephone network or the like.

The command is received by the server at step 505. The server then searches its media database 334 (FIG. 3) for the action to be performed. Once an appropriate action is located, the server performs the action at step 508. For example, the action may be to update a media library on the server, send the portable media device another media file, or send the portable media device an additional menu. In other words, the action may require transmitting a data back to the portable media device.

If the action requires sending data back to the portable media device at step 509, the communication procedures 322 (FIG. 3) on the server preferably transmit the data back to the portable media device, at step 518, in the form of an additional command. For example, the additional command may instruct the portable media device to add an additional menu to the portable media device's navigation database. Such a command preferably includes procedures that the portable media device can execute.

If the additional command is to add an additional menu to the navigation database 234 (FIG. 2), the text to audio synthesizer 328 (FIG. 3) on the server may first synthesize a description of the additional menu into speech or audio at step 516 before transmitting the command and the synthesized audio description to the portable media device at step 518. The synthesized audio description is preferably contained in a compressed audio file, such as an MP3 file describing the associated action. Thereafter, the command including the synthesized audio description is transmitted to the portable device, at step 518.

Subsequently, the command (and the synthesized audio description, if appropriate) is received by the portable media device at step 526. If a synthesized audio description did not accompany the command, and the command is to update the navigation database, then the text to audio synthesizer 228 (FIG. 2) on the portable media device itself synthesizes the description of the additional menu into speech or audio at step 528. The navigation database 234 (FIG. 2) is then updated by associating the additional menu with an action to be performed on the portable media device at step 530. In a preferred embodiment, the operating system on the portable media device is a database driven menu structure. Accordingly, updating the navigation database effectively updates the portable media device's operating system.

The synthesized audio description is then stored in the media database 230, at step 532. The additional menu in the navigation database 234 (FIG. 2) preferably points to the synthesized audio description stored as a media file in the media database 234 (FIG. 2). Alternatively, the audio description is stored directly in the navigation database 234 (FIG. 2).

The second method is initiated when a user of the portable media device requests the client computer to perform an action, as indicated by the solid line. As described above: an audio prompt is played at step 501; a user's input is received at step 502; a determination is made that the input requires a remote computer, such as the client computer, to perform an action at step 503; and a command is transmitted by the portable media device 108 (FIG. 1) to the client computer at step 502. This command is communicated by the communication procedures 222 (FIG. 2) on the portable device to the client computer. The command is received, at step 510, by the communication procedures 322 (FIG. 3) on the client computer 102 (FIG. 1). The client computer then searches its action database 330 (FIG. 3) for the action to be performed. Once an appropriate action is located the client computer performs the action at step 512. For example, the action may be to update a media library on the client computer, send the portable media device another media file, or send the portable media device an additional menu. In other words, the action may require transmitting data back to the portable media device. It should be appreciated that step 512 may be initiated by the client computer itself.

If the action requires sending data back to the portable media device at step 509, the communication procedures 322 (FIG. 3) on the client computer preferably transmit the data back to the portable media device, at step 524, in the form of an additional command. For example, the additional command may instruct the portable media device to add an additional menu to the portable media device's navigation database. Such a command preferably includes procedures that the portable media device can execute.

If the additional command is to add an additional menu to the navigation database 234 (FIG. 2), the text to audio synthesizer 328 (FIG. 3) on the client computer may first synthesize a description of the additional menu into speech or audio at step 514 before transmitting the command and the synthesized audio description to the portable media device at step 524. The synthesized audio description is preferably contained in a compressed audio file, such as an MP3 file describing the associated action. Thereafter, the command including the synthesized audio description is transmitted to the portable device, at step 524.

Subsequently, the command (and the synthesized audio description, if appropriate) is received by the portable media device at step 526. If a synthesized audio description did not accompany the command, and the command is to update the navigation database, then the text to audio synthesizer 228 (FIG. 2) on the portable media device itself synthesizes the description of the additional menu into speech or audio at step 528. The navigation database 234 (FIG. 2) is then updated by associating the additional menu with an action to be performed on the portable media device at step 530. In a preferred embodiment, the operating system on the portable media device is a database driven menu structure. Accordingly, updating the navigation database effectively updates the portable media device's operating system.

The synthesized audio description is then stored in the media database 230, at step 532. The additional menu in the navigation database 234 (FIG. 2) preferably points to the synthesized audio description stored as a media file in the media database 234 (FIG. 2). Alternatively, the audio description is stored directly in the navigation database 234 (FIG. 2).

The third method is where the client computer requests the server to perform an action, as indicated by the dashed line. The communication procedures 322 (FIG. 3) on the client computer 102 (FIG. 1) transmit a command to the server 106 (FIG. 1) to perform an action at step 506. This command preferably contains the name of a particular action to be performed

The command is received by the server at step 504, which then searches its media database 334 (FIG. 3) for the requested command. Once the command is located, at step 508, the server performs the action at step 508. For example, the action may be to send the client computer additional menus. In other words, the action may require transmitting a data back to the client computer.

If the action requires sending data back to the client computer, at step 509, the communication procedures 322 (FIG. 3) on the server preferably transmit the data back to the client computer, at step 518, in the form of an additional command. For example, the additional command may instruct the client computer to store additional menus for later download to the portable media device.

If the additional command is to send additional menus back to the client computer for later download to the portable media device, then the text to audio synthesizer 328 (FIG. 3) on the server may first synthesize a description of the additional menu into speech or audio at step 516 before transmitting the command and the synthesized audio description to the client computer at step 518. The synthesized audio description is preferably contained in a compressed audio file, such as an MP3 file describing the associated action. Thereafter, the command including the synthesized audio description is transmitted to the client computer, at step 518.

Subsequently, the action (and the synthesized audio description, if appropriate) is received by the client computer at step 520 and the action performed by the client computer at step 522. For example, the client computer may perform an action to store additional menus for later download to the portable media device. Thereafter, whenever the portable media device requests the client computer to perform the action of sending the portable media device additional menus, as described above in relation to the first method, and shown by the solid line, the requested additional menus can be sent to the portable media device.

In an alternative embodiment, instead of synthesizing the description of an additional menu, the audio description of the additional menu is human generated or customizable. For example, such a human generated audio description may form part of a third party's branding or might assist in a quick identification of a menu description. Known voice over specialists may be used to generate a few widely used audio descriptions that are downloaded from the server 106 (FIG. 1).

FIG. 6 is a flow chart of a method 600 for navigating through an audio prompt menu structure on the portable device 102 (FIG. 1). It should, however, be appreciated that the following description of the method 600 is merely exemplary, as the menu structure may contain any number of permutations, levels, etc. Furthermore, for ease of explanation only one typical path of the method 600 will be described.

The method 600 is started at step 602, such as by a user pressing a power button or opening the cover 432 (FIG. 4B). This automatically invokes the player procedures 226 (FIG. 2) to play a main menu media file 236(1)-(N) (FIG. 2) from the navigation database 234 (FIG. 2) at step 604. In a preferred embodiment, this media file is an audio prompt. Each menu 1-N 236(1)-(N) (FIG. 2) is associated with a particular media file stored in the media database 230. For instance, the main menu is associated with an MP3 file containing a main menu audio prompt. As one example, the portable media device plays a main audio menu through the headset 216 (FIG. 2), such as “Welcome to NEUROS, press or say “1” for genres, press or say “2” for artists, press or say “3” for titles, please press or say “4” for searching, . . . , press or say “main” to repeat.”

The operating system 220 (FIG. 2) then waits for user input. If the user presses or says “1”, the player procedures 226 (FIG. 2) play a first menu 236(1)-(N) (FIG. 2) from the navigation database 234 (FIG. 2), at step 614; if the user presses or says “2”, the player procedures 226 (FIG. 2) play a second menu 236(1)-(N) (FIG. 2) from the navigation database 234 (FIG. 2) at step 616; if the user presses or says “n”, the player procedures 226 (FIG. 2) play a nth menu 236(1)-(N) (FIG. 2) from the navigation database 234 (FIG. 2) at step 618; etc. By playing a menu, it is meant that an audio description associated with the menu, and stored as a media file, is played. For example, if the user presses “1,” the player procedures play: “You have selected artists. For ABBA press or say “1,” for Badu, Erykah press or say “2,” for Clapton, Eric press or say “3,” . . . , press or say “back” to repeat.”

If the user presses or says “main,” at step 612 the player procedures 226 (FIG. 2) repeat the main menu 236(1)-(N) (FIG. 2) from the navigation database 234 (FIG. 2) at step 604.

The operating system 220 (FIG. 2) then waits for user input after playing the first menu at step 614. If the user presses or says “1,” the player procedures 226 (FIG. 2) play a first submenu 236(1)-(N) (FIG. 2), consisting of a list of media file descriptions, from the navigation database 234 (FIG. 2) at step 628; if the user presses or says “2,” the player procedures 226 (FIG. 2) play a second submenu 236(1)-(N) (FIG. 2), consisting of a list of media file descriptions, from the navigation database 234 (FIG. 2) at step 630; if the user presses or says “n,” the player procedures 226 (FIG. 2) play a nth submenu 236(1)-(N) (FIG. 2), consisting of a list of media file descriptions, from the navigation database 234 (FIG. 2) at step 632; etc. For example, if the user presses “1,” the player procedures play: “You have selected ABBA. Press or say “1” for Alley Cat, press or say “2” for Baby, . . . , press or say “back” to repeat.” If the user presses or says “back,” at step 626, the player procedures 226 (FIG. 2) repeat the first menu at step 614.

The operating system 220 (FIG. 2) then waits for user input after playing the first submenu at step 628. The player procedures 226 (FIG. 2) then play a list of actions for the selected media file (1, 2, or n) from the commands database 230 (FIG. 2) and/or the media database 234 (FIG. 2) at step 642. For example, if the user presses “1,” the player procedures play: “You have selected Alley Cat, press or say “play” to play the media, press or say “forward” to fast forward through the media, press or say “rewind” to rewind the media, press or say “delete” to delete the media, . . . , press or say “back” to repeat.”

The operating system 220 (FIG. 2) then waits for user input after playing the list of commands at step 642. Once the input is received, the OS determines, at step 670, whether a supplied user input is for an action to be performed on the portable media device, or whether the action is to be performed by the client computer or server. If the action is to be performed on the portable media device (670-yes), then the OS determines the precise user input.

If the user presses or says “play,” at step 648, the player procedures play the media file at step 658; if the user presses or says “forward,” the player procedures fast forward through the media file at step 660; if the user presses or says “rewind,” the player procedures rewind the media file at step 662; and if the user presses or says “back,” the player procedures repeat the list of commands at step 642. The actions to be performed on the portable media device, denoted by “other” at step 654 and 664 may also include deleting media on the portable media device; creating playlists on the portable media device; grouping media into a favorites group on the portable media device; browsing a list of media, where the media is stored on the client computer or server; or the like. In addition, the actions to be performed on the portable media device denoted by “other” at step 654 and 664, may also include transmitting commands to the server or the client computer as described above in relation to FIG. 5. For example, the portable media device may send feedback to the server or the client computer. Such feedback may include a command requesting the server or the client computer to perform an action, such as updating a library or storing feedback about the user's media likes or dislikes in a user profile (not shown). If the user presses or says “main” at any time, at step 612, the player procedures will play the main menu at step 604.

If the OS 220 (FIG. 2) determines that the action is not to be performed on the portable media device (670-No), then the OS and communication procedures 222 (FIG. 2) transmits a command to either the client computer or the server the next time that the portable media device communicates with the client computer or the server, such as during synchronization at step 672. The communication procedures then wait until such synchronization occurs at step 674. When synchronization occurs (674-Yes), the command is transmitted to the client computer or the server at step 676. Such commands may instruct the client computer or the server to provide more information about selected media; provide feedback about selected media, such as I like this song, I do not like this song, or play this song less/more frequently; request a recommendation of similar media to that selected; instruct the client computer to delete media; instruct the client computer to email the media; instruct the client computer to add the track to a playlist or favorites group; or the like.

Although not shown, certain actions may interrupt playing media while such actions are performed, such as playing an audio prompt menu. Indeed, in a preferred embodiment, a number of keys are reserved for dedicated actions, such as deleting a media file, finding out more information about the media file being played, or the like. Also, when audio prompts are being played, the media currently being played is muted or paused to make the audio prompts easier to hear. Furthermore, in a preferred embodiment, users can configure whether to introduce each media file before playback with an audio description of that media file.

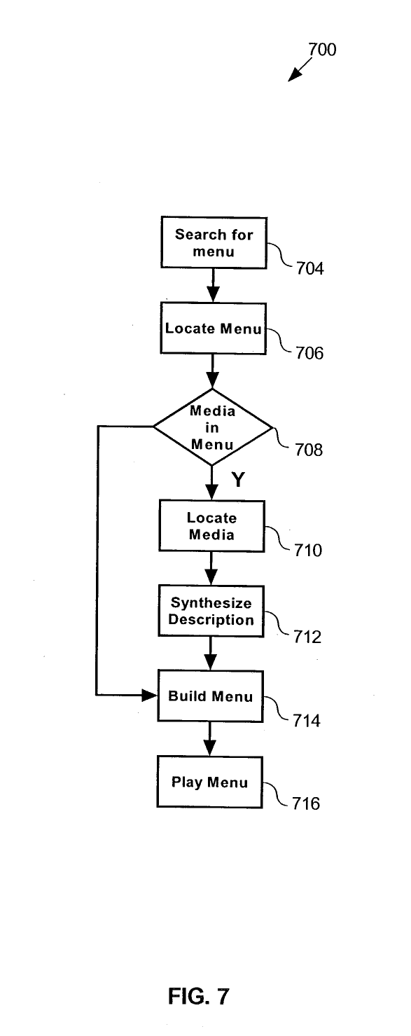

FIG. 7 is a flow chart of a method 700 for dynamically generating an audio prompt menu. When a menu is needed by the operating system (OS) 220 (FIG. 2) on the portable media device, as described above, the OS searches the navigation database 234 (FIG. 2) for the appropriate navigation menu at step 704. The appropriate menu is determined by interpreting the various input commands or signals received from the user, such as a keypad input or the like. Once the OS has located the appropriate menu at step 706, the OS determines whether it needs to synthesize any media descriptions into audio for the menu at step 708. For example, the menu may require listing the names of the artists of the media currently stored on the portable media device. In an alternative embodiment, the OS also determines whether there are any command descriptions that need to be synthesized into audio.

If the menu requires presenting part of a media file's description contained in the media file's metadata (708-Yes), then the OS locates the media file at step 710 and synthesizes the required textual description into audio at step 712. For example, if the menu requires listing the titles of various audio tracks, the ID3 tag for each MP3 audio track is synthesized into audio. This audio description may be stored in the cache 244 or in the media database 234 as a separate media file. If the menu does not require presenting part of a media file's description (708-No), or once the description has been synthesized, at step 712, the OS builds the appropriate menu at step 714. The menu is then played at step 716. Alternatively, the menu may be stored for later use. The text-to-audio synthesis is created by the text to audio synthesizer 228 (FIG. 2) on the portable media device. Alternatively, this text-to-audio conversion can occur at the time the media is first transferred onto the portable media device, and stored as a media file in the media database for later use. In yet another alternative embodiment, the client computer and/or the server can convert the metadata into an audio file that is associated with the media file and transferred to the portable media device together with the media file itself. It should be appreciated that all audio prompt menu media files or media file descriptions are typically small in size relative to the regular media files themselves.

Accordingly, only menus that are relevant are presented or played to the user, i.e., menus are created dynamically. For example, an artist may have an additional menu (XIM) associated with it that allows a user to purchase more media from the artist. Therefore, individual menus may preferably be added, modified, or deleted independently of other menus in the navigation database, as such menus are preferably not hardcoded into the portable media device's firmware.

In addition, actions performed on the portable media device that require an associated action to be performed on the client computer or server transmit a command to the client computer or server containing the action to be executed on the client computer or server. For example, if a media file is deleted on the portable media device, a command is sent to the client computer instructing the client computer to delete the same file or to remove the file from a playlist listing the media stored on the portable media device.

Because a digital audio player inherently possesses all the requisite components required for playing audio, a voice prompt driven menu structure can be added for little or no additional cost. Also, by incorporating an audio prompt menu structure, the portable media device does not require a display. Accordingly, the portable media device can not only be much smaller than devices that require a display, but can also be significantly cheaper than these devices. In addition, such an audio prompt menu structure has obvious advantages for a visually impaired user.

The foregoing descriptions of specific embodiments of the present invention are presented for purposes of illustration and description. They are not intended to be exhaustive or to limit the invention to the precise forms disclosed. Obviously many modifications and variations are possible in view of the above teachings. For example, any of the aforementioned embodiments or methods, may be combined with one another, especially if a combination of embodiments or methods can be used to assist in the identification of an audio track. It should be appreciated to one skilled in the art that all the elements of the portable device 108 listed below need not be present in all embodiments of the invention and are merely included for exemplary purposes. Also, most of the menu and interactivity functionality envisioned here are based on the proprietary OS described in co-pending U.S. patent application Ser. No. 10/273,565, but it should be appreciated that the invention disclosed here could be used on a great variety of menu driven devices or the like. Furthermore, although the menu structure has been described in terms of an audio prompt menu structure, it should be appreciated that a video prompt menu structure may also me used. The embodiments were chosen and described in order to best explain the principles of the invention and its practical applications, to thereby enable others skilled in the art to best utilize the invention and various embodiments with various modifications as are suited to the particular use contemplated. Furthermore, the order of steps in the method are not necessarily intended to occur in the sequence laid out. It is intended that the scope of the invention be defined by the following claims and their equivalents.

1. A method for using an audio prompt menu on a portable media device, comprising:
storing an audio prompt on a portable media device;
playing said audio prompt menu on said portable media device;
receiving in response to said audio prompt menu an input from a user of said portable media device; and
transmitting a command to a remote computer, where said command requests said remote computer to perform an action based on said input.

2. The method of claim 1, further comprising, prior to said storing, synthesizing a textual description of a menu into said audio prompt.

3. The method of claim 2, wherein said synthesizing occurs on said portable media device.

4. The method of claim 2, wherein said synthesizing occurs at said remote computer.

5. The method of claim 1, further comprising, prior to said storing:
receiving at a portable media device a command for adding an additional menu to a navigation database on said portable audio device; and
invoking said command to update said navigation database, where said audio prompt is an audio description of said additional menu.

6. The method of claim 5, further comprising, before said receiving, requesting at said portable media device said additional menu from said remote computer.

7. The method of claim 5, further comprising, after said receiving, synthesizing a textual description of said additional menu into said audio prompt.

8. The method of claim 7, wherein said synthesizing comprises synthesizing said textual description into a compressed audio format.

9. The method of claim 5, further comprising, before said receiving:
playing another audio prompt on said portable media device;
receiving at said portable media device an input from a user requesting said an additional menu; and
transmitting a request for said additional menu to a remote server.

10. The method of claim 5, wherein said additional menu contains instructions selected from a group consisting of: deleting a media file, instructing another remote computer to purchase a media file, instructing another remote computer to recommend media, instructing said remote computer to delete a media file, instructing said remote computer to add a media file, instructing said remote computer to modify a media file, instructing said remote computer to email a media file, and instructing said remote computer to delete an index of a media file from a playlist.

11. The method of claim 1, further comprising:
playing another audio prompt on said portable media device;
receiving at said portable media device an input from said user; and
performing an action on said portable media device based on said input.

12. The method of claim 9, further comprising, before said transmitting, synthesizing a textual description of said additional menu into said audio description at said remote computer.

13. A method for updating an audio prompt menu structure on a portable media device, comprising:
receiving at a portable media device a command for adding an additional menu to a navigation database on said portable audio device;
invoking said command to update said navigation database; and
storing an audio description of said additional menu on said portable media device for later use in an audio prompt menu structure.

14. The method of claim 13, further comprising, before said receiving, requesting at said portable media device said additional menu from said remote computer.

15. The method of claim 13, further comprising, after said receiving, synthesizing a textual description of said additional menu into said audio description.

16. The method of claim 15, wherein said synthesizing comprises synthesizing said textual description into a compressed audio format.

17. The method of claim 16, wherein said compressed audio format is MPEG-1 Audio Layer 3 (MP3).

18. The method of claim 13, further comprising, before said receiving:
playing an audio prompt on said portable media device;
receiving at said portable media device an input from a user requesting said additional menu; and
transmitting a request for said additional menu to a remote server.

19. The method of claim 13, wherein said additional menu contains instructions selected from a group consisting of: deleting a media file, instructing another remote computer to purchase a media file, instructing another remote computer to recommend media, instructing said remote computer to delete a media file, instructing said remote computer to add a media file, instructing said remote computer to modify a media file, instructing said remote computer to email a media file, and instructing said remote computer to delete an index of a media file from a playlist.

20. The method of claim 13, further comprising:
playing said audio description on said portable media device;
receiving at said portable media device an input from said user; and
performing an action on said portable media device based on said input.

21. The method of claim 13, further comprising, before said receiving:
transmitting a request from said portable audio player for said additional menu to a remote computer;
receiving said request at said remote computer;
locating said action on said remote computer; and
transmitting said action to said portable audio player.

22. A method for dynamically generating an audio prompt menu on a portable media device, comprising:
determining that a menu structure on a portable device requires presenting an description of a media file;
locating a textual description of said media file on said portable media device;
synthesizing said textual description into an audio description on said portable media device;
generating an audio prompt menu that at least partially incorporates said audio description; and
playing said audio prompt menu on said portable media device.

23. The method of claim 22, further comprising:
receiving in response to said audio prompt menu an input from a user of said portable media device;
transmitting a command to a remote computer based on said input, where said command requests said remote computer to perform an action.

24. A portable media device, comprising:
a portable media device housing containing:
a processor;
a power source;
a user interface device;
communications circuitry;
at least one input/output (i/o) port; and
a memory, comprising:
an operating system;
a media database;
communication procedures for communicating with a remote computer;
instructions for storing an audio prompt in said media database;
instructions for playing said audio prompt menu;
instructions for receiving in response to said audio prompt menu an input from a user of said portable media device via said user input interface; and
instructions for transmitting a command to a remote computer via said communications circuitry, where said command requests said remote computer to perform an action based on said input.

25. The portable media device of claim 24, wherein said memory further comprises a text to audio synthesizer.

26. The portable media device of claim 24, wherein said memory further comprises media stored in said media database.
